(19) United States
(12) Patent Application Publication
(10) Pub. No.: US 2024/0429030 A1
(43) Pub. Date: Dec. 26, 2024

(54) PLASMA TREATMENT APPARATUS

(71) Applicant: Kioxia Corporation, Tokyo (JP)

(72) Inventor: Kazuya EMURA, Yatomi Aichi (JP)

(73) Assignee: Kioxia Corporation, Tokyo (JP)

(21) Appl. No.: 18/732,852

(22) Filed: Jun. 4, 2024

(30) Foreign Application Priority Data
Jun. 21, 2023 (JP) 2023-102033

(51) Int. Cl. H01J 37/32

(52) U.S. Cl. CPC H01J 37/32715; H01J 37/32733; H01J 2237/3341

(57) ABSTRACT

A plasma treatment apparatus including a stage, an edge ring, a drive mechanism, and a plasma generation portion is provided. The stage is disposed in a treatment chamber. The stage includes a main surface. A substrate is placed on the main surface. The edge ring is disposed in the treatment chamber. The edge ring surrounds the main surface when viewed from a direction perpendicular to the main surface. The drive mechanism can drive the edge ring in a direction along the main surface. The plasma generation portion can generate plasma in a space adjacent to the main surface in the treatment chamber.

### CROSS-REFERENCE TO RELATED APPLICATION(S)

This application is based upon and claims the benefit of priority from Japanese Patent Application No. 2023-102033, filed Jun. 21, 2023, the entire contents of which are incorporated herein by reference.

### FIELD

Embodiments described herein relate generally to a plasma treatment apparatus.

### BACKGROUND

A plasma treatment apparatus treats a substrate placed on a stage with plasma. In the plasma treatment apparatus, an edge ring disposed outside the stage may be worn by the plasma.

### DESCRIPTION OF THE DRAWINGS

FIG. 1 is a cross-sectional view illustrating a schematic configuration of a plasma treatment apparatus according to at least one embodiment.

FIG. 2 is a perspective view illustrating a configuration of an edge ring and a drive mechanism in the embodiment.

FIG. 3 is a plan view illustrating the configuration of the edge ring and the drive mechanism in the embodiment.

FIG. 4 is a cross-sectional view illustrating an operation of the edge ring and the drive mechanism in the embodiment.

FIG. 5 is a perspective view illustrating a configuration of bevel gears in the embodiment.

FIGS. 6A-6C are a cross-sectional view illustrating a configuration and an operation of another part of the drive mechanism in the embodiment.

FIGS. 7A-7D are a cross-sectional view illustrating an operation of the plasma treatment apparatus according to the embodiment.

FIGS. 8A-8C are a perspective view illustrating an operation of the edge ring in the embodiment.

FIGS. 9A-9C are a plan view illustrating the operation of the edge ring in the embodiment.

FIGS. 10A-10C are a cross-sectional view illustrating an operation of members adjacent to each other in the embodiment.

FIGS. 11A-11C are a perspective view illustrating a configuration and an operation of an edge ring in a modification example.

FIGS. 12A-12C are a cross-sectional view illustrating a configuration and an operation of members adjacent to each other in the modification example.

### DETAILED DESCRIPTION

Embodiments provide a plasma treatment apparatus that can reduce the influence due to wear of an edge ring.

In general, according to at least one embodiment, a plasma treatment apparatus including a stage, an edge ring, a drive mechanism (drive), and a plasma generation portion (plasma generator) is provided. The stage is disposed in a treatment chamber. The stage includes a main surface. A substrate is placed on the main surface. The edge ring is disposed in the treatment chamber. The edge ring surrounds the main surface when viewed from a direction perpendicular to the main surface. The drive mechanism can drive the edge ring in a direction along the main surface. The plasma generation portion can generate plasma in a space adjacent to the main surface in the treatment chamber.

A plasma treatment apparatus according to an embodiment will be described in detail below with reference to the accompanying drawings. It should be noted that the present disclosure is not limited to the embodiment.

### Embodiment

A plasma treatment apparatus according to an embodiment treats a substrate placed on a stage with plasma. A plasma treatment apparatus 1 may be an etching apparatus that etches the substrate with plasma, or may be a film formation apparatus that deposits a predetermined film on the substrate with plasma. The etching apparatus using plasma is, for example, a reactive ion etching (RIE) apparatus. The film formation apparatus using plasma is, for example, a plasma chemical vapor deposition (CVD) apparatus.

Hereinafter, a case where the plasma treatment apparatus 1 is an etching apparatus using plasma will be exemplified. However, the concept of the present embodiment can also be applied to a case where the plasma treatment apparatus 1 is a film formation apparatus using plasma.

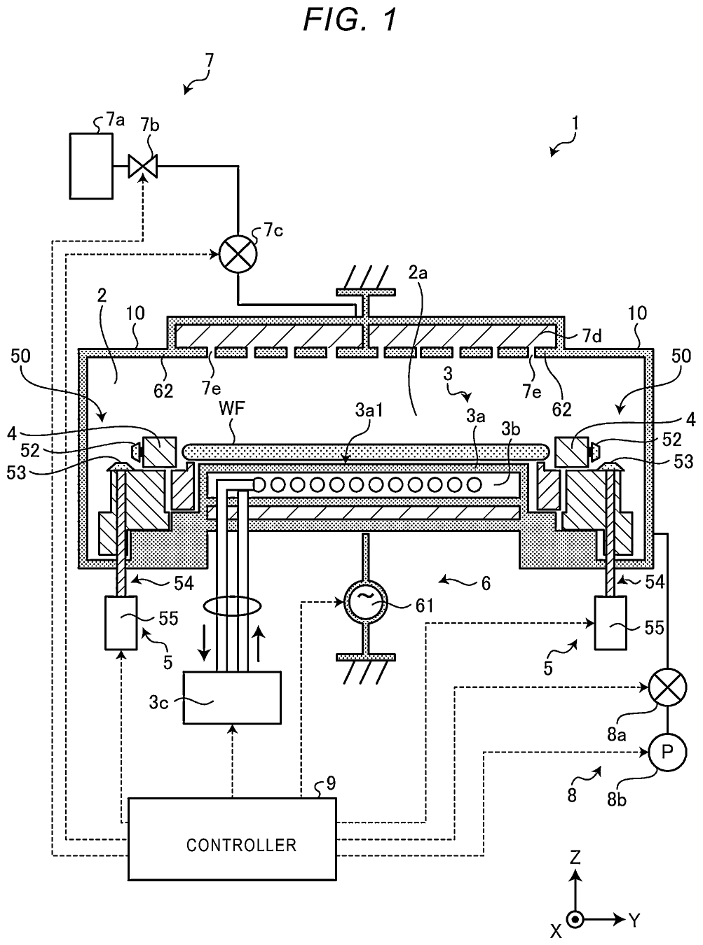

The plasma treatment apparatus 1 can be configured as illustrated in FIG. 1. FIG. 1 is a cross-sectional view illustrating a schematic configuration of the plasma treatment apparatus 1.

The plasma treatment apparatus 1 includes a treatment chamber 2, a stage 3, an edge ring 4, a drive mechanism 5, a gas supply system 7, an exhaust system 8, a plasma generation portion 6, and a controller 9. In the following description, a direction perpendicular to a main surface 3a1 of the stage 3 is a Z direction, and two directions perpendicular to the Z direction and orthogonal to each other are an X direction and a Y direction.

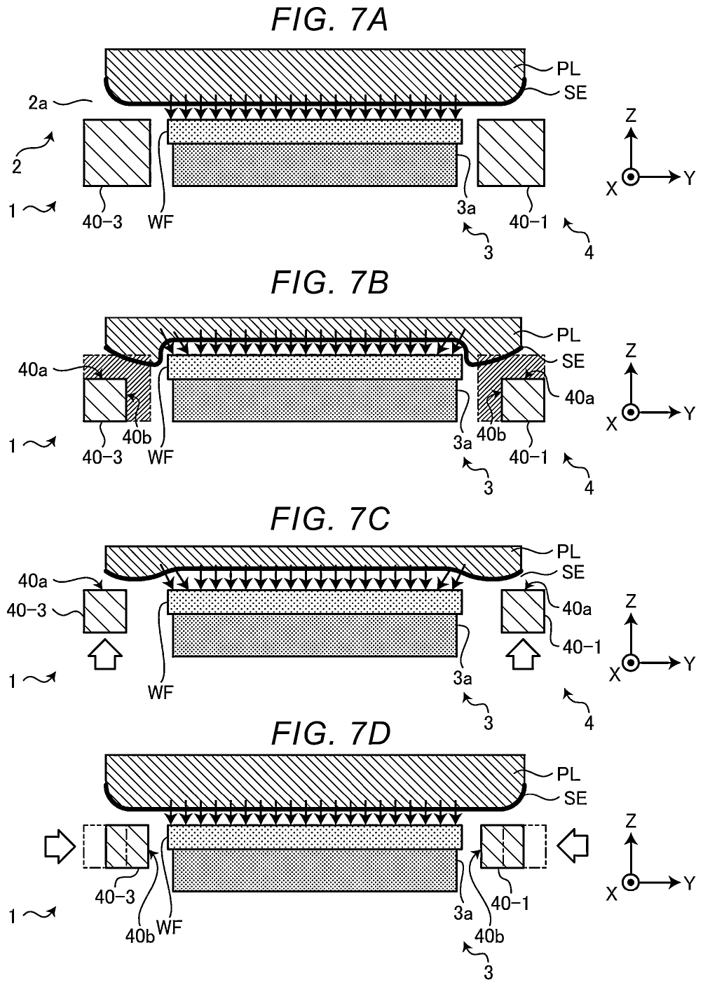

The treatment chamber 2 is a chamber in which plasma PL (see FIG. 7) is generated and is formed by a treatment container 10. The treatment container 10 may have a shape that is flat in an XY direction. The treatment container 10 may have a substantially circular cylinder shape that is flat in the XY direction, or may have a substantially rectangular column shape that is flat in the XY direction.

The stage 3 is disposed on a bottom surface side (−Z side) in the treatment chamber 2. The stage 3 includes an electrode 3a, a suction mechanism 3b, and a drive portion 3c. The electrode 3a is insulated from the treatment container 10 via an insulation material (not illustrated). The electrode 3a includes the main surface 3a1 on a +Z side. The main surface 3a1 extends in the XY direction. A treatment target substrate WF such as a silicon wafer is placed on the main surface 3a1. The suction mechanism 3b is provided at the main surface 3a1 of the stage 3. The drive portion 3c is connected to the suction mechanism 3b and moves the suction mechanism 3b under the control of the controller 9, whereby the treatment target substrate WF can be sucked to the main surface 3a1. The electrode 3a may have a shape that is flat in the XY direction. The electrode 3a may have a substantially circular cylinder shape that is flat in the XY direction. The electrode 3a is formed of, for example, metal such as stainless steel or aluminum.

The suction mechanism 3b may be a vacuum chuck, and the drive portion 3c may be a vacuum device. The suction mechanism 3b may include a suction hole exposed at the main surface 3a1, and the vacuum device may be capable of vacuum suctioning of the treatment target substrate WF to the main surface 3a1 via the suction hole.

The suction mechanism 3b may be an electrostatic chuck, and the drive portion 3c may be a power supply. The power supply may supply power to the electrostatic chuck so that the treatment target substrate WF can be electrostatically held to the main surface 3a1. FIG. 1 illustrates a configuration example in which the suction mechanism 3b is an electrostatic chuck and the drive portion 3c is a power supply.

The edge ring 4 is disposed on the bottom surface side (−Z side) in the treatment chamber 2. The edge ring 4 has a substantially cylindrical shape with a center axis along a Z axis. The edge ring 4 has a substantially annular shape in an XY plan view. The edge ring 4 is disposed on an outer side in the XY direction with respect to the stage 3. The edge ring 4 surrounds the main surface 3a1 when viewed from the +Z direction.

It should be noted that, in the treatment chamber 2, when a plasma PL region is formed, a sheath SE region having a potential gradient is also formed between the plasma PL region and the electrode 3a. In the present specification, a boundary surface between the plasma PL region and the sheath SE region is referred to as a sheath SE. The sheath SE region corresponds to a region in which a sheath electric field is formed between the sheath SE and the electrode 3a.

The edge ring 4 flattens the sheath SE up to the outer side of the stage 3 in the XY direction when the plasma PL is generated in the treatment chamber 2. Desirably, a Z height of a surface of the edge ring 4 on the +Z side is substantially equal to the Z height of a surface of the treatment target substrate WF placed on the stage 3.

An inner diameter of the edge ring 4 corresponds to an outer diameter of the electrode 3a and is slightly larger than the outer diameter of the electrode 3a. The inner diameter of the edge ring 4 corresponds to an outer diameter of the treatment target substrate WF and is slightly larger than the outer diameter of the treatment target substrate WF.

An outer diameter of the edge ring 4 corresponds to an inner diameter of the treatment container 10 and is smaller than the inner diameter of the treatment container 10.

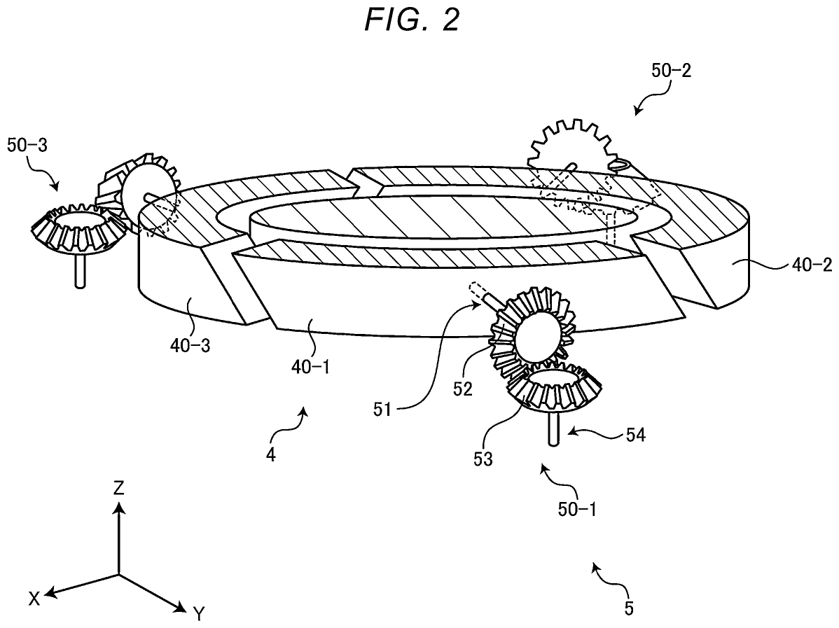

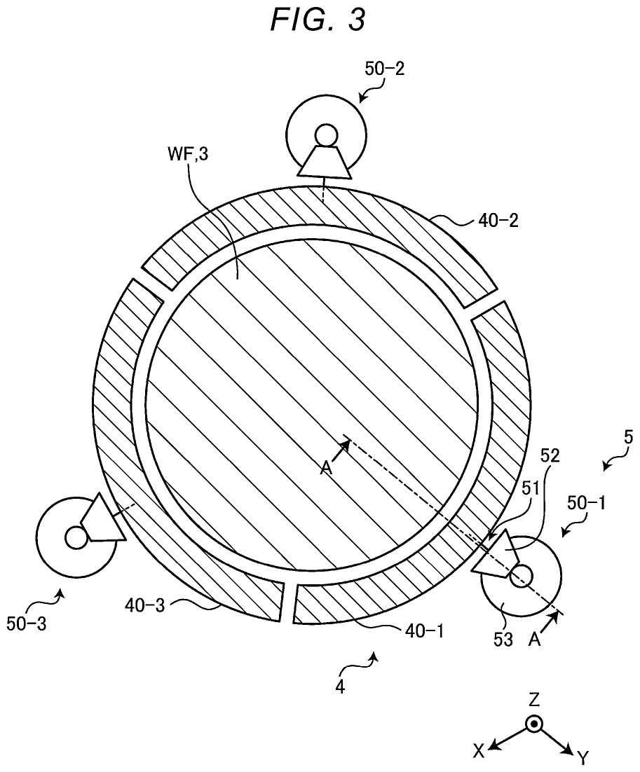

As illustrated in FIG. 2 and FIG. 3, the edge ring 4 includes a plurality of members 40-1 to 40-3 that can be separated in a circumferential direction. FIG. 2 is a perspective view illustrating a configuration of the edge ring 4 and the drive mechanism 5. FIG. 3 is a plan view illustrating the configuration of the edge ring 4 and the drive mechanism 5. FIG. 2 and FIG. 3 illustrate a configuration in which the edge ring 4 includes three members 40-1 to 40-3, but the number of members in the edge ring 4 is not limited to three, and may be two or may be four or more.

The plurality of members 40-1 to 40-3 is arranged along the circumferential direction. Two members adjacent to each other in the circumferential direction out of the plurality of members 40-1 to 40-3 have end portions in the circumferential direction, the end portions facing each other and at least partially overlapping each other when seen through from the Z direction.

For example, the end portion of the member 40-1 on the member 40-2 side and the end portion of the member 40-2 on the member 40-1 side face each other and at least partially overlap each other when seen through from the Z direction. The end portion of the member 40-1 on the member 40-2 side includes a flat bottom surface on the −Z side and includes an inclined end surface on the member 40-2 side, the inclined end surface being inclined such that the Z height decreases toward the member 40-2. The end portion of the member 40-2 on the member 40-1 side includes a flat upper surface on the +Z side and includes an inclined end surface on the member 40-1 side, the inclined end surface being inclined such that the Z height increases toward the member 40-1. The inclined end surface of the member 40-1 and the inclined end surface of the member 40-2 face each other and may have a substantially constant clearance therebetween in the XY direction.

Similarly, the end portion of the member 40-1 on the member 40-3 side and the end portion of the member 40-3 on the member 40-1 side face each other and at least partially overlap each other when seen through from the Z direction. The end portion of the member 40-1 on the member 40-3 side includes a flat upper surface on the +Z side and includes an inclined end surface on the member 40-3 side, the inclined end surface being inclined such that the Z height increases toward the member 40-3. The end portion of the member 40-3 on the member 40-1 side includes a flat bottom surface on the −Z side and includes an inclined end surface on the member 40-1 side, the inclined end surface being inclined such that the Z height decreases toward the member 40-1. The inclined end surface of the member 40-1 and the inclined end surface of the member 40-3 face each other and may have a substantially constant clearance therebetween in the XY direction.

Each of the members 40 can be made of any material. Each of the members 40 may be made of a material containing silicon as a main component, may be made of a material containing silicon carbide as a main component, or may be made of a material containing quartz as a main component.

The drive mechanism 5 illustrated in FIG. 1 can drive the edge ring 4 in a direction intersecting the main surface 3a1 (e.g., the Z direction) as well as can drive the edge ring 4 in a direction along the main surface 3a1 (e.g., the XY direction). The drive mechanism 5 drives the edge ring 4 so as to decrease the outer diameter of the edge ring 4.

As illustrated in FIG. 2 and FIG. 3, the drive mechanism 5 includes a plurality of drive portions 50-1 to 50-3. The plurality of drive portions 50-1 to 50-3 correspond to the plurality of members 40-1 to 40-3. Each of the drive portions 50-1 to 50-3 can drive the corresponding member 40 independently from each other.

Each of the drive portions 50 can drive the corresponding member 40 in the direction intersecting the main surface 3a1 (e.g., the Z direction) as well as can drive the corresponding member 40 in the direction along the main surface 3a1 (e.g., the XY direction). Each of the drive portions 50 can drive the corresponding member 40 in an ascending direction (e.g., the +Z direction) as well as can drive the corresponding member 40 in a direction approaching the stage 3.

The drive portion 50 includes a shaft 51, a bevel gear 52, a bevel gear 53, a shaft 54, and an actuator 55.

The actuator 55 is disposed on the −Z side of the treatment container 10. The actuator 55 retains the shaft 54 in a drivable manner. The shaft 54 has an axis along the Z direction and extends in an axial direction. The actuator 55 rotates the shaft 54 around the axis and raises the shaft 54 in the Z direction under the control of the controller 9. That is, the actuator 55 has a configuration in which a mechanism for rotating operation and a mechanism for raising operation are integrated in one place. Accordingly, the configuration of the actuator 55 can be downsized as compared with a case where the mechanism for rotating operation and the mechanism for raising operation are separately disposed.

The actuator 55 may include a rotary motor and a linear motor, and the shaft 54 may be rotated around the axis using the rotary motor, and the shaft 54 may be raised in the Z direction using the linear motor. The actuator 55 may include two rotary motors and a cam mechanism, and the shaft 54 may be rotated around the axis using the first rotary motor, and the rotary motion of the second rotary motor may be converted into a translational motion by the cam mechanism so that the shaft 54 is raised in the Z direction by the translational motion.

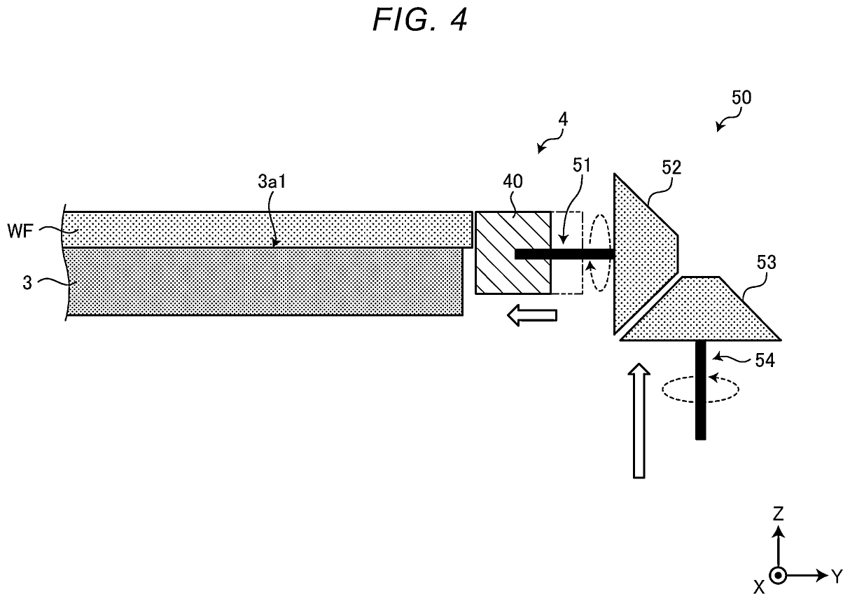

The shaft 54 is disposed between the actuator 55 and the bevel gear 53. One end of the shaft 54 is retained by the actuator 55 and the other end is coupled to the bevel gear 53. As indicated by a dotted arrow in FIG. 4, the rotational movement around the axis of the shaft 54 can be transmitted as the rotational movement around a central axis of the bevel gear 53. As indicated by an open arrow in FIG. 4, the ascending movement of the shaft 51 in the Z direction can be transmitted as the ascending movement of the bevel gear 53 in the Z direction. FIG. 4 is a cross-sectional view illustrating an operation of the edge ring 4 and the drive mechanism 5. FIG. 4 illustrates a cross section taken along axes of the shafts 51 and 54.

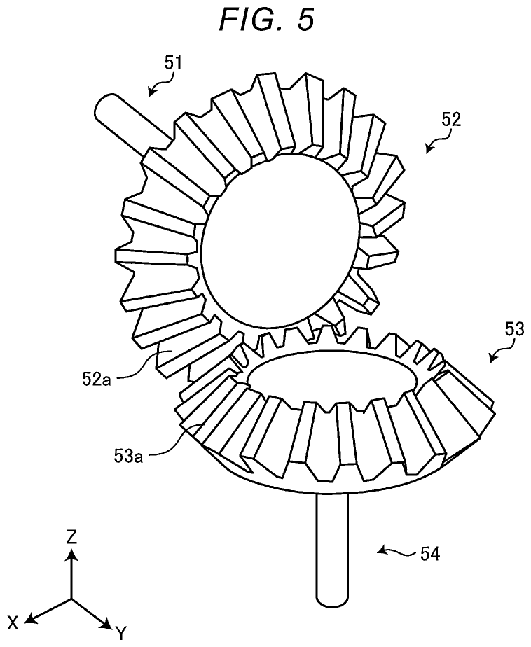

The bevel gear 53 is engaged with the bevel gear 52. The bevel gear 53 has the central axis along the direction intersecting the main surface 3a1 (e.g., the Z direction) and has a substantially truncated cone shape with reference to the central axis. The bevel gear 53 can rotate around the central axis. The bevel gear 53 includes a plurality of teeth 53a at an inclined surface of the substantially truncated cone shape as illustrated in FIG. 5. FIG. 5 is a perspective view illustrating a configuration of the bevel gears 52 and 53. Each of the teeth 53a extends from the central axis in a radial direction.

That is, the drive portion 50 is configured such that the rotational movement and the ascending movement are concurrently transmitted from the actuator 55 to the shaft 51. Accordingly, the configuration of the drive portion 50 can be downsized as compared with a case where the rotational movement and the ascending movement are separately transmitted from the actuator 55 to the shaft 51, allowing the downsizing of the treatment container 10.

The bevel gear 52 illustrated in FIG. 2 and FIG. 3 has a central axis along the shaft 51 and has a substantially truncated cone shape with reference to the central axis. The bevel gear 52 can rotate around the central axis. The bevel gear 52 includes a plurality of teeth 52a at an inclined surface of the substantially truncated cone shape as illustrated in FIG. 5. Each of the teeth 52a extends from the central axis in the radial direction. The plurality of teeth 52a is engaged with the plurality of teeth 53a. As indicated by dotted arrows in FIG. 4, the rotational movement around the central axis of the bevel gear 53 is transmitted as the rotational movement around the central axis of the bevel gear 52. The ascending movement of the bevel gear 53 in the Z direction is transmitted as the ascending movement of the bevel gear 52 in the Z direction.

The shaft 51 illustrated in FIG. 2 and FIG. 3 is disposed between the member 40 and the bevel gear 52, has an axis along the main surface 3a1 in a direction away from the stage 3, and extends in the axial direction. One end of the shaft 51 is connected to the member 40 and the other end is coupled to the bevel gear 52. As indicated by the dotted arrow in FIG. 4, the rotational movement around the central axis of the bevel gear 52 can be transmitted as the rotational movement around the axis of the shaft 51. The ascending movement of the bevel gear 52 in the Z direction can be transmitted as the ascending movement of the shaft 51 in the Z direction.

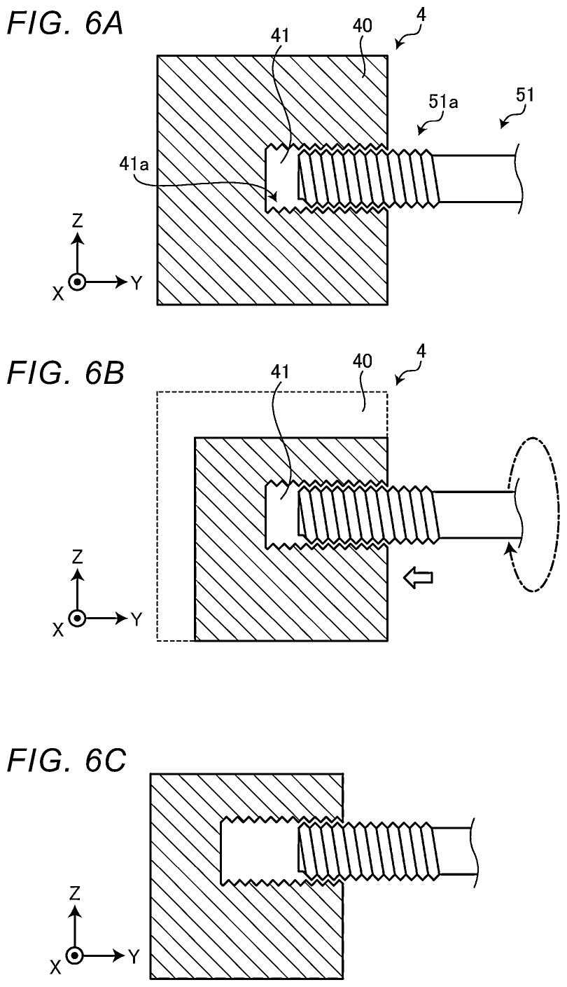

As illustrated in FIG. 6A, a feed screw 51a is provided at the vicinity of the one end of the shaft 51. The member 40 includes a screw hole 41 at an outer circumferential side. The screw hole 41 includes, at an internal surface thereof, a thread groove 41a corresponding to the feed screw 51a. The feed screw 51a at the one end of the shaft 51 is inserted into the screw hole 41 of the member 40. A helical ridge of the feed screw 51a is screwed into the thread groove 41a of the screw hole 41. The shaft 51 rotates around the axis as illustrated in FIG. 6B, whereby the insertion depth of the one end in the screw hole 41 changes as illustrated in FIG. 6C. As a result, the member 40 can be fed in a direction approaching the stage 3 in the axial direction as indicated by an open arrow in FIG. 4. The shaft 51 can raise the member 40 in the Z direction by being raised in the Z direction.

The gas supply system 7 illustrated in FIG. 1 can supply treatment gas to the treatment chamber 2. The gas supply system 7 includes a gas cylinder 7a, an on-off valve 7b, a regulation valve 7c, a diffusion chamber 7d, and a supply hole 7e. Opening and closing of the on-off valve 7b is controlled by the controller 9. The opening degree of the regulation valve 7c is controlled by the controller 9.

The exhaust system 8 can discharge the treatment gas after treatment from the treatment chamber 2. The exhaust system 8 includes a regulation valve 8a and a vacuum pump 8b. The opening degree of the regulation valve 8a is controlled by the controller 9. Driving of the vacuum pump 8b is controlled by the controller 9.

The plasma generation portion 6 generates plasma in a space 2a isolated from the electrode 3a in the treatment chamber 2. The plasma generation portion 6 includes a high-frequency power supply 61 and an upper electrode 62. The upper electrode 62 may be grounded to a ground potential. The high-frequency power supply 61 supplies high-frequency power to the electrode 3a under the control of the controller 9.

Accordingly, in the space 2a in the treatment chamber 2, discharge of the treatment gas occurs, the plasma PL is generated as illustrated in FIG. 7A, and ions (e.g., F+ and CF3+) as well as radicals are generated from the treatment gas. FIG. 7 is a cross-sectional view illustrating an operation of the plasma treatment apparatus 1.

When the plasma PL is generated in the space 2a in the treatment chamber 2, the sheath SE region having a potential gradient is also formed between the plasma PL region and the electrode 3a. Accordingly, the ions generated together with the radicals in the plasma PL are accelerated from the sheath SE to the surface of the treatment target substrate WF (on the electrode 3a side) as indicated by arrows in FIG. 7A. The acceleration directions of the ions are substantially the same. As a result, the etching process of the treatment target substrate WF can be performed.

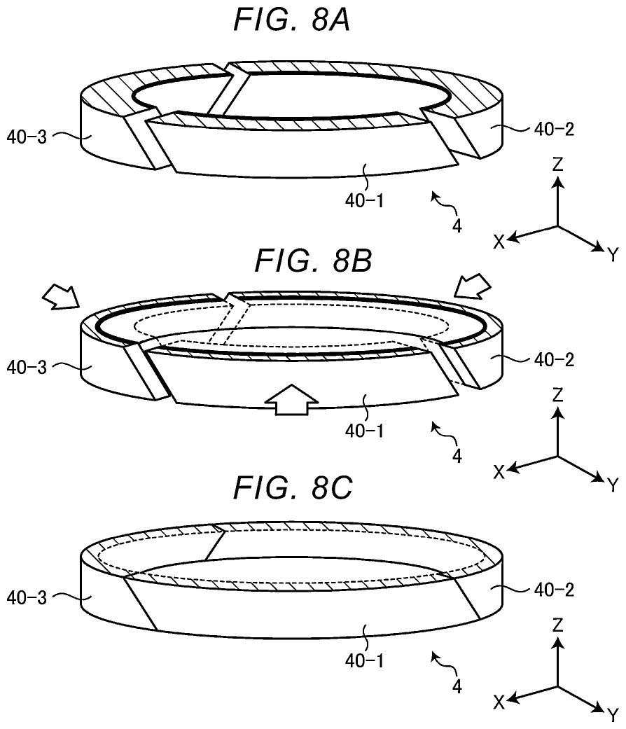

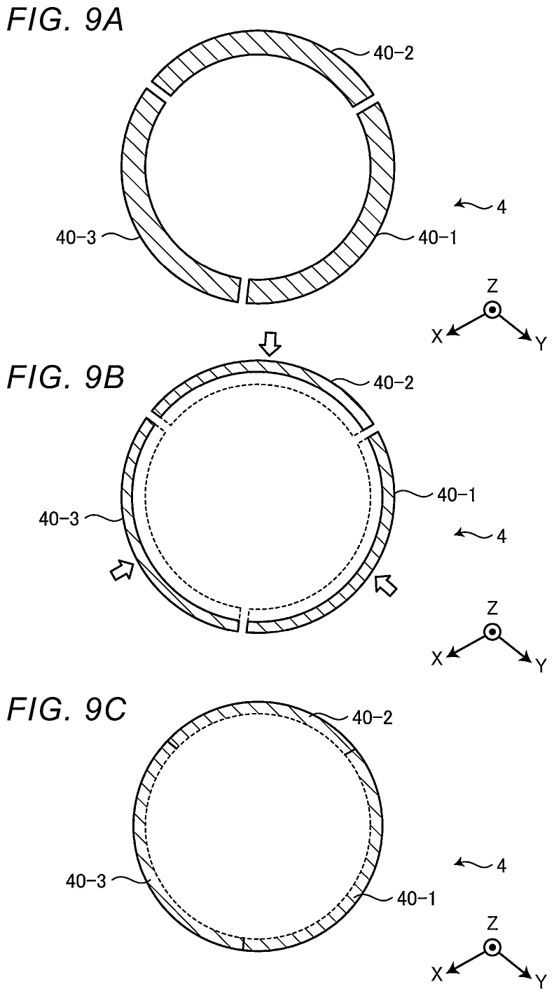

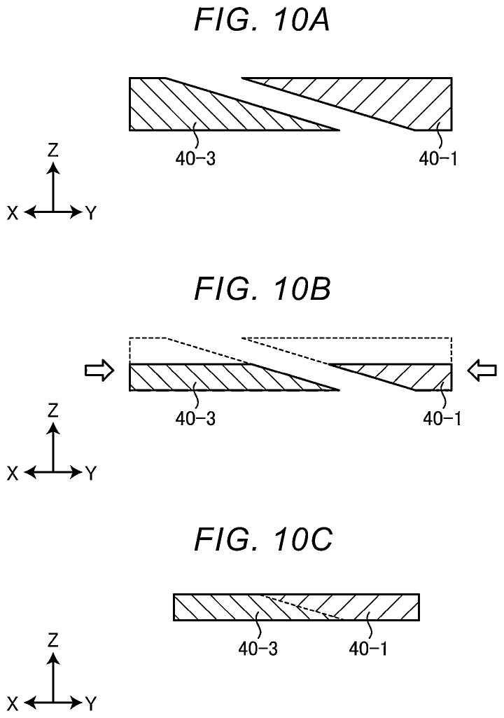

At this time, the plurality of members 40-1 to 40-3 of the edge ring 4 are separated from each other in the circumferential direction as illustrated in FIG. 8A, FIG. 9A, and FIG. 10A. FIG. 8 is a perspective view illustrating an operation of the edge ring 4. FIG. 9 is a plan view illustrating the operation of the edge ring 4. FIG. 10 is a cross-sectional view illustrating an operation of the members 40-1 and 40-3 adjacent to each other. FIG. 10 illustrates a cross section obtained by cutting the members 40-1 and 40-3 adjacent to each other along the Z direction and the circumferential direction.

When the operation of the plasma treatment apparatus 1 is continuously performed, each of the members 40-1 to 40-3 of the edge ring 4 is slightly etched by the ions or the like, and thus worn as indicated by dotted lines in FIG. 7B, FIG. 8B, FIG. 9B, and FIG. 10B. As a result, in each of the members 40-1 to 40-3, the Z height of a surface 40a on the +Z side decreases, and the XY distance of a surface 40b facing the stage 3 from the stage 3 increases.

Accordingly, the sheath SE is distorted in the vicinities of outer ends of the treatment target substrate WF. As a result, a sheath electric field between the sheath SE and the electrode 3a is distorted in the vicinities of the outer ends of the treatment target substrate WF, and an acceleration directions of the ions are distorted in the vicinities of the outer ends of the treatment target substrate WF as indicated by arrows in FIG. 7B, and thus the accuracy of the etching process of the treatment target substrate WF may be deteriorated.

Thus, the controller 9 controls the drive mechanism 5 when the cumulative operation time of the plasma treatment apparatus 1 reaches a predetermined time. In accordance with this control, the drive mechanism 5 raises each of the members 40-1 to 40-3 of the edge ring 4 in the +Z direction as indicated by arrows in FIG. 7C and moves each of the members 40-1 to 40-3 in the XY direction so as to approach the stage 3 as indicated by arrows in FIG. 7D, FIG. 8B, and FIG. 9B. For example, the drive mechanism 5 can raise each of the members 40-1 to 40-3 in the +Z direction such that the Z height of the surface on the +Z side becomes equal to the Z height of the surface of the treatment target substrate WF. The drive mechanism 5 can move each of the members 40-1 to 40-3 in the XY direction such that the distance between the surface on the stage 3 side and the stage 3 becomes equal to a predetermined distance. The predetermined distance can be experimentally determined in advance.

At this time, the drive mechanism 5 may cause the plurality of members 40-1 to 40-3 of the edge ring 4 to approach each other in the circumferential direction as illustrated in FIG. 8C, FIG. 9C, and FIG. 10C. The drive mechanism 5 may cause the plurality of members 40-1 to 40-3 of the edge ring 4 to come into contact with each other in the circumferential direction. As a result, each of the members 40-1 to 40-3 can be moved in the XY direction so as to approach the stage 3.

Accordingly, the sheath SE becomes approximately flat in the XY direction as illustrated in FIG. 7D. As a result, the distortion of the sheath electric field between the sheath SE and the electrode 3a is relieved, and the acceleration directions of the ions becomes substantially the same as indicated by arrows in FIG. 7D, and thus the accuracy of the etching process of the treatment target substrate WF can be improved.

As described above, in the plasma treatment apparatus 1 according to the embodiment, the drive mechanism 5 can drive the edge ring 4 in the direction intersecting the main surface 3a1 (e.g., the Z direction) as well as can drive the edge ring 4 in the direction along the main surface 3al (e.g., the XY direction). For example, when an upper surface and an inner surface of the edge ring 4 are worn, the drive mechanism 5 raises the plurality of members 40-1 to 40-3 of the edge ring 4 in the +Z direction and moves the members 40-1 to 40-3 in the XY direction so as to approach the stage 3. As a result, when the plasma PL is generated in the treatment chamber 2, the sheath SE can be approximately flattened in the XY direction, and the distortion of the sheath electric field between the sheath SE and the electrode 3a can be relieved, and thus the accuracy of the etching process by the plasma treatment apparatus 1 can be improved.

It should be noted that the plasma treatment apparatus 1 is not limited to the plasma treatment apparatus of a parallel plate type exemplified in FIG. 1, but may be a plasma treatment apparatus of another type. The concept of the present embodiment can be also applied to a plasma treatment apparatus of an inductive coupling plasma (ICP) type or a plasma treatment apparatus of an electron cyclotron resonance (ECR) type.

As a modification example of the embodiment, two members adjacent to each other in the circumferential direction out of a plurality of members 140-1 to 140-3 of an edge ring 104 may have, at end portions thereof in the circumferential direction, structures that can be engaged with each other.

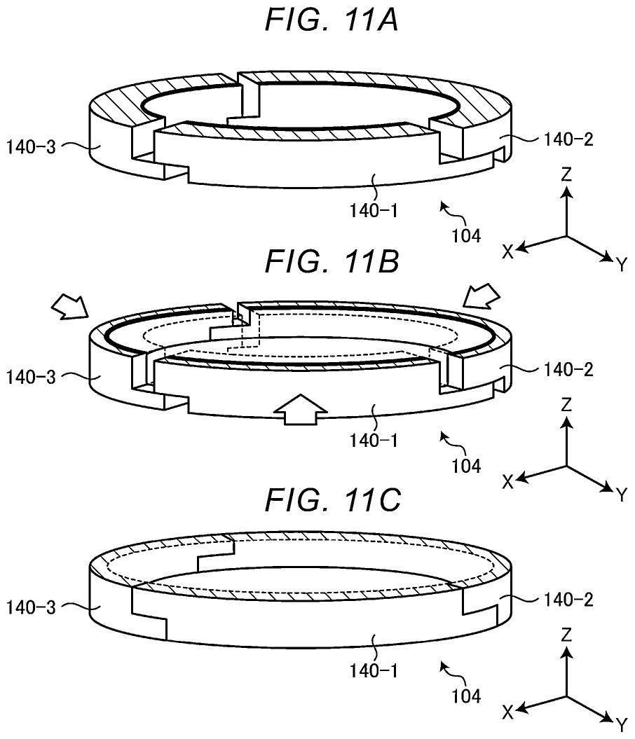

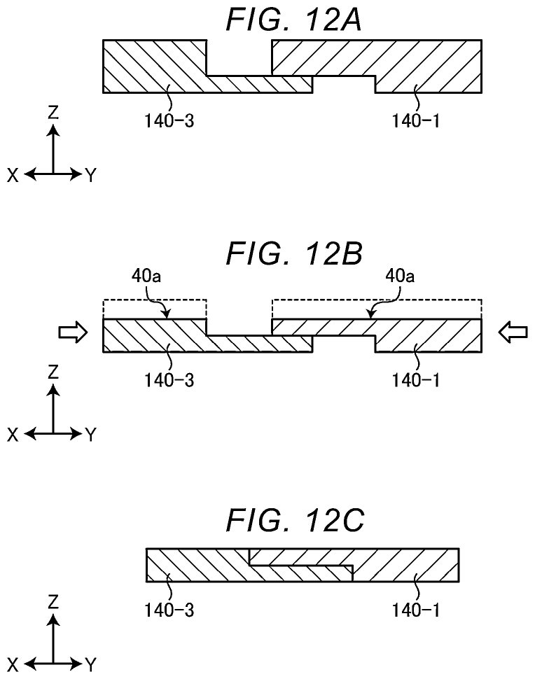

As illustrated in FIG. 11A and FIG. 12A, for example, the end portion of the member 140-1 on the member 140-2 side includes a flat bottom surface on the −Z side and includes a stepped structure on the member 140-2 side, the Z height of the stepped structure decreasing stepwise toward the member 140-2. FIG. 11 is a perspective view illustrating a configuration and an operation of the edge ring 104 in the modification example of the embodiment. FIG. 12 is a cross-sectional view illustrating a configuration and an operation of the members 140-1 and 140-3 adjacent to each other in the modification example of the embodiment. FIG. 12 illustrates a cross section obtained by cutting the members 140-1 and 140-3 adjacent to each other along the Z direction and the circumferential direction. The end portion of the member 140-2 on the member 140-1 side includes a flat upper surface on the +Z side and includes a stepped structure on the member 140-1 side, the Z height of the stepped structure increasing stepwise toward the member 140-1. The stepped structure of the member 140-1 and the stepped structure of the member 140-2 face each other, and respective step portions extending in the Z direction may have a substantially constant clearance therebetween in the XY direction and respective deck portions extending in the XY direction may be partially in contact with each other.

Similarly, the end portion of the member 140-1 on the member 140-3 side includes a flat upper surface on the +Z side and includes a stepped structure on the member 140-3 side, the Z height of the stepped structure increasing stepwise toward the member 140-3. The end portion of the member 140-3 on the member 140-1 side includes a flat bottom surface on the −Z side and includes a stepped structure on the member 140-1 side, the Z height of the stepped structure decreasing stepwise toward the member 140-1. The stepped structure of the member 140-1 and the stepped structure of the member 140-3 face each other, and respective step portions extending in the Z direction may have a substantially constant clearance therebetween in the XY direction and respective deck portions extending in the XY direction may be partially in contact with each other.

Immediately after the start of the operation of the plasma treatment apparatus 1, the plurality of members 140-1 to 140-3 of the edge ring 104 are separated from each other in the circumferential direction as illustrated in FIG. 11A and FIG. 12A.

When the operation of the plasma treatment apparatus 1 is continuously performed, each of the members 140-1 to 140-3 of the edge ring 104 is slightly etched by ions or the like, and thus worn as indicated by dotted lines in FIG. 11B and FIG. 12B. As a result, in each of the members 140-1 to 140-3, the Z height of the surface 40a on the +Z side decreases, and the XY distance of the surface 40b facing the stage 3 from the stage 3 increases (see FIG. 7B).

Thus, the controller 9 controls the drive mechanism 5 when the cumulative operation time of the plasma treatment apparatus 1 reaches a predetermined time. In accordance with this control, the drive mechanism 5 raises each of the members 140-1 to 140-3 of the edge ring 104 in the +Z direction (see FIG. 7C) and moves each of the members 140-1 to 140-3 in the XY direction so as to approach the stage 3 as indicated by arrows in FIG. 11B and FIG. 12B. For example, the drive mechanism 5 can raise each of the members 140-1 to 140-3 in the +Z direction such that the Z height of the surface on the +Z side becomes equal to the Z height of the surface of the treatment target substrate WF. The drive mechanism 5 can move each of the members 140-1 to 140-3 in the XY direction such that the distance between the surface on the stage 3 side and the stage 3 becomes equal to a predetermined distance. The predetermined distance can be experimentally determined in advance.

At this time, the drive mechanism 5 may cause the plurality of members 140-1 to 140-3 of the edge ring 104 to approach each other in the circumferential direction as illustrated in FIG. 11C and FIG. 12C. The drive mechanism 5 may cause the plurality of members 140-1 to 140-3 of the edge ring 104 to come into contact with each other in the circumferential direction. As a result, each of the members 140-1 to 140-3 can be moved in the XY direction so as to approach the stage 3.

Accordingly, the sheath SE becomes approximately flat in the XY direction as illustrated in FIG. 7D. As a result, the distortion of the sheath electric field between the sheath SE and the electrode 3a is relieved, and the acceleration directions of the ions becomes substantially the same as indicated by the arrows in FIG. 7D, and thus the accuracy of the etching process of the treatment target substrate WF can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma treatment apparatus comprising:
a stage disposed in a treatment chamber, the stage including a main surface arranged to support a substrate;
an edge ring disposed in the treatment chamber, the edge ring surrounding the main surface when viewed from a direction perpendicular to the main surface;
a drive configured to drive the edge ring in a direction along the main surface; and
a plasma generator configured to generate plasma in a space adjacent to the main surface in the treatment chamber.

2. The plasma treatment apparatus according to claim 1, wherein the drive is configured to drive the edge ring such that an outer diameter is decreased.

3. The plasma treatment apparatus according to claim 1, wherein the drive is configured to drive the edge ring in the direction along the main surface and a direction intersecting the main surface.

4. The plasma treatment apparatus according to claim 1, wherein
the edge ring includes a plurality of members that are separable in a circumferential direction, and
the drive includes a plurality of drive portions corresponding to the plurality of members.

5. The plasma treatment apparatus according to claim 4, wherein the plurality of members is arranged along the circumferential direction.

6. The plasma treatment apparatus according to claim 4, wherein two members, from among the plurality of members, adjacent to each other in the circumferential direction have end portions in the circumferential direction, the end portions facing each other and at least partially overlapping each other viewed from the direction perpendicular to the main surface.

7. The plasma treatment apparatus according to claim 4, wherein two members, from among the plurality of members, adjacent to each other in the circumferential direction have, at end portions of the two members in the circumferential direction, structures arranged to be engaged with each other.

8. The plasma treatment apparatus according to claim 4, wherein the plurality of drive portions are configured to drive the members independently from each other.

9. The plasma treatment apparatus according to claim 4, wherein the drive portions are configured to drive the members in the direction along the main surface.

10. The plasma treatment apparatus according to claim 4, wherein the drive portions are configured to drive the members in the direction along the main surface and a direction intersecting the main surface.

11. The plasma treatment apparatus according to claim 10, wherein
each of the drive portions includes
a first shaft having one end provided with a feed screw and extending in the direction along the main surface, the feed screw inserted into a screw hole of each of the members,
a first bevel gear coupled to another end of the first shaft,
a second bevel gear engaged with the first bevel gear, and
a second shaft having one end coupled to the second bevel gear and extending in the direction intersecting the main surface.

12. The plasma treatment apparatus according to claim 1, wherein the apparatus is a film formation apparatus.

13. The plasma treatment apparatus according to claim 12, wherein the apparatus is a chemical vapor deposition apparatus.

14. The plasma treatment apparatus according to claim 1, wherein the apparatus is an etching apparatus.

15. The plasma treatment apparatus according to claim 14, wherein the apparatus is a reactive ion etching apparatus.

16. The plasma treatment apparatus according to claim 1, wherein the stage includes a suctioning mechanism configured to hold the substrate to the main surface.

17. The plasma treatment apparatus according to claim 16, wherein the suctioning mechanism includes a vacuum chuck.
